(19) United States
(12) Patent Application Publication
(10) Pub. No.: US 2024/0341121 A1
(43) Pub. Date: Oct. 10, 2024

(54) OLED DEVICE AND MANUFACTURING METHOD THEREFOR, AND DISPLAY PANEL

(71) Applicants: Chongqing BOE Display Technology Co., Ltd., Chongqing (CN); BOE Technology Group Co., Ltd., Beijing (CN)

(72) Inventors: Yanyu LIU, Beijing (CN); Lu YANG, Beijing (CN); Dawei SHI, Beijing (CN); Keyuan LI, Beijing (CN); Yang XIE, Beijing (CN); Can HUANG, Beijing (CN); Xiaosong WEN, Beijing (CN); Zixin LIN, Beijing (CN); Jiachen GUO, Beijing (CN)

(73) Assignees: Chongqing BOE Display Technology Co., Ltd., Chongqing (CN); BOE Technology Group Co., Ltd., Beijing (CN)

(21) Appl. No.: 18/294,550

(22) PCT Filed: Apr. 22, 2022
(86) PCT No.: PCT/CN2022/088525

§ 371 Date: Feb. 2, 2024

(51) Int. Cl. H10K 59/122; H10K 59/12; H10K 59/173

(52) U.S. Cl. CPC H10K 59/122; H10K 59/1201; H10K 59/173

(57) ABSTRACT

The present disclosure relates to an OLED device and a manufacturing method thereof, and a display panel. The OLED device includes: a substrate; an anode layer and a pixel-defining layer, provided on a side of the substrate, the pixel-defining layer including a plurality of pixel-defining structures, and adjacent pixel-defining structures defining a pixel unit; a first organic layer, covering the anode layer and the pixel-defining layer; a light-emitting layer, provided on a side of the first organic layer away from the substrate and within the pixel unit; and a cathode layer, covering the light-emitting layer and the first organic layer. The first organic layer includes at least one open groove.

### CROSS-REFERENCE TO RELATED APPLICATION

The present application is a U.S. National Stage of International Application No. PCT/CN2022/088525 filed on Apr. 22, 2022, the entire contents of which are incorporated herein by reference.

### TECHNICAL FIELD

The present disclosure relates to the field of display technology, and specifically, to an OLED device and a manufacturing method thereof, and a display panel.

### BACKGROUND

The OLED (Organic Light-Emitting Diode) differs from the traditional LCD product in that it does not need an external backlight. The OLED emits light when electric current flows through EL-emitting material thereof and causes electroluminescence. Therefore, the OLED display device has the advantages of being lighter, thinner, and having a larger viewing angle.

An EL structure of a common flexible OLED product includes three EL light-emitting layers of RGB, and a common layer including an HTL layer and a HIL layer is usually provided below the EL layer for series connection. In the related art, the OLED device has a problem of lateral leakage in the common layer during operation.

It is to be noted that the information disclosed in the above background section is only used to enhance the understanding of the background of the present disclosure, and thus may include information that does not constitute the prior art known to those skilled in the art.

### SUMMARY

The present disclosure provides an OLED device and a manufacturing method thereof, and a display panel.

One aspect of the present disclosure provides an OLED device, including: a substrate; an anode layer and a pixel-defining layer, provided on a side of the substrate, the pixel-defining layer including a plurality of pixel-defining structures, and adjacent pixel-defining structures defining a pixel unit; a first organic layer, covering the anode layer and the pixel-defining layer; a light-emitting layer, provided on a side of the first organic layer away from the substrate and within the pixel unit; and a cathode layer, covering the light-emitting layer and the first organic layer, wherein the first organic layer includes at least one open groove.

In an embodiment of the present disclosure, the pixel-defining structure includes a first sidewall, a second sidewall and a third sidewall, and the third sidewall is connected between the first sidewall and the second sidewall; and the first organic layer includes a first extending part, a second extending part, and a third extending part, and the first extending part, the second extending part and the third extending part are provided to respectively correspond to the first sidewall, the second sidewall and the third sidewall; and the open groove is provided in at least one of the first extending part, the second extending part and the third extending part.

In an embodiment of the present disclosure, the open groove is provided with a modification layer therein for insulation.

In an embodiment of the present disclosure, a ratio of a thickness of the modification layer to a thickness of the first organic layer at a same location as the modification is greater than or equal to 1/9 and less than or equal to ⅘.

In an embodiment of the present disclosure, the thickness of the modification layer is greater than or equal to 1000 Å and less than or equal to 2000 Å.

In an embodiment of the present disclosure, a ratio of an extension length of the modification layer to a length of a sidewall of the pixel-defining structure corresponding to the modification layer is greater than or equal to 1/10 and less than or equal to 1.

In an embodiment of the present disclosure, a material of the modification layer is SiO₂ or an insulating material doped with negative ions.

In an embodiment of the present disclosure, a surface energy of the modification layer is less than a surface energy of the pixel-defining layer.

In an embodiment of the present disclosure, an orthographic projection, on the substrate, of the anode layer is partially overlapped with an orthographic projection, on the substrate, of the pixel-defining structure adjacent to the anode layer, and an orthographic projection, on the substrate, of the light-emitting layer is within the orthographic projection, on the substrate, of the anode layer; and an orthographic projection, on the substrate, of the open groove is not overlapped with the orthographic projection, on the substrate, of the light-emitting layer.

In an embodiment of the present disclosure, the open groove is open towards the pixel-defining structure or away from the pixel-defining structure.

In an embodiment of the present disclosure, one open groove is provided, the one open groove is provided in the first extending part of the first organic layer, the open groove is provided with a modification layer therein for insulation, and an orthographic projection, on the substrate, of the third sidewall of the pixel-defining structure is within an orthographic projection, on the substrate, of the modification layer.

A second aspect of the present disclosure further provides a method of manufacturing the OLED device according to any embodiment of the present disclosure, including: providing a substrate; forming an anode layer and a pixel-defining layer on the substrate; forming a buffer layer on the pixel-defining layer; forming a pixel-defining structure and a buffer structure provided on the pixel-defining structure by patterning the buffer layer and the pixel-defining layer using a patterning process; forming a first organic layer on the pixel-defining structure and the buffer structure; forming an open groove by etching away the buffer structure using an etching process; and forming a cathode layer on the first organic layer.

A second aspect of the present disclosure further provides a method of preparing the OLED device according to the embodiment of the present disclosure, including: providing a substrate; forming an anode layer and a pixel-defining layer on the substrate; forming a buffer layer on the pixel-defining layer; forming a pixel-defining structure and a modification layer by patterning the buffer layer and the pixel-defining layer using a patterning process; forming a first organic layer on the pixel-defining structure and the modification layer; and forming a cathode layer on the first organic layer.

In an embodiment of the present disclosure, forming the buffer layer on the pixel-defining layer includes: forming the buffer layer by depositing a first material on the pixel-defining layer using a chemical vapor deposition process.

In an embodiment of the present disclosure, the method further includes, after forming the buffer layer: modifying the buffer layer using a low surface energy modification process such that the surface energy of the buffer layer is lower than the surface energy of the pixel-defining layer.

In an embodiment of the present disclosure, modifying the buffer layer using the low surface energy modification process includes: immersing the buffer layer into a predetermined solution for a predetermined time; and drying the buffer layer at a predetermined temperature.

In an embodiment of the present disclosure, a material of the buffer layer is SiO₂, and immersing the buffer layer into the predetermined solution for the predetermined time includes: immersing the buffer layer of SiO₂ into a 1H, 1H,2H,2H-perfluoroalkyltriethoxysilane solution for 120 s, wherein the 1H, 1H,2H,2H-perfluoroalkyltriethoxysilane solution contains 1H,1H,2H,2H-perfluoroalkyltriethoxysilane with a mass fraction of 0.5% to 1.5% with respect to a solvent, and the solvent is water or ethyl alcohol, accordingly, drying the buffer layer at the predetermined temperature includes: drying the buffer layer of SiO₂ at 120° C.

In an embodiment of the present disclosure, forming the buffer layer on the pixel-defining layer includes: forming the buffer layer by doping a surface of the pixel-defining layer with negative ions using an ion implantation process.

A third aspect of the present disclosure further provides a display panel including the OLED device according to any embodiment of the present disclosure.

It should be understood that the above general description and the following detailed descriptions are exemplary and explanatory only and do not limit the embodiments of the present disclosure.

### BRIEF DESCRIPTION OF THE DRAWINGS

The accompanying drawings herein are incorporated into and form a part of the specification, illustrate embodiments consistent with the present disclosure, and are used in conjunction with the specification to explain the principle of the present disclosure. Obviously, the accompanying drawings in the following description are only some of the embodiments of the present disclosure, and those skilled in the art may obtain other accompanying drawings from these drawings without creative work.

FIG. 1 is a schematic diagram of a structure of an OLED device according to an implementation of the present disclosure;

FIG. 2 is a schematic structural diagram of one pixel-defining structure in FIG. 1;

FIG. 3 is a schematic arrangement diagram of open grooves in one pixel-defining structure in FIG. 1;

FIG. 4 is a schematic arrangement diagram of open grooves in another pixel-defining structure in FIG. 1;

FIG. 5 is a schematic structural diagram of an OLED device according to another implementation of the present disclosure;

FIG. 6 is a schematic structural diagram of a portion of an OLED device according to an implementation of the present disclosure;

FIG. 7 is a schematic structural diagram of an OLED device according to yet another implementation of the present disclosure;

FIG. 8 is a schematic structural diagram of a portion of an OLED device according to another implementation of the present disclosure;

FIG. 9 is a schematic structural diagram of a portion of an OLED device according to yet another implementation of the present disclosure;

FIG. 10 is a schematic structural diagram of a portion of an OLED device according to yet another implementation of the present disclosure;

FIG. 11 is a schematic structural diagram of a portion of an OLED device according to yet another implementation of the present disclosure;

FIG. 12 is a schematic structural diagram in which an anode layer and a pixel-defining layer are formed on a substrate according to an implementation of the present disclosure;

FIG. 13 is a schematic structural diagram in which a buffer layer is formed according to an implementation of the present disclosure;

FIG. 14 is a schematic structural diagram in which a pixel-defining structure and a buffer structure are formed according to an implementation of the present disclosure;

FIG. 15 is a schematic structural diagram in which a first organic layer is formed according to an implementation of the present disclosure;

FIG. 16 is a schematic structural diagram in which an open groove is formed according to an implementation of the present disclosure;

FIG. 17 is a schematic structural diagram in which an OLED device is formed according to an implementation of the present disclosure;

FIG. 18 is a schematic diagram of surface energy modification according to an implementation of the present disclosure;

FIG. 19a is a schematic diagram of a process for forming a buffer layer according to an implementation of the present disclosure;

FIG. 19b is a schematic structural diagram of a buffer layer formed according to the process shown in FIG. 19a;

FIG. 20 is a schematic structural diagram in which a pixel-defining structure and a modification layer are formed according to an implementation of the present disclosure;

FIG. 21 is a schematic structural diagram in which a first organic layer is formed according to an implementation of the present disclosure; and

FIG. 22 is a schematic structural diagram of an OLED device formed according to an implementation of the present disclosure.

### DETAILED DESCRIPTION

Example embodiments will now be described more fully with reference to the accompanying drawings. However, the example embodiments may be implemented in a variety of forms and should not be construed as being limited to the embodiments set forth herein; rather, these embodiments are provided so that the present disclosure is comprehensive and complete and the concept of the example embodiments is conveyed to those skilled in the art in a comprehensive manner. The same reference numerals in the drawings denote the same or similar structures, and thus their detailed descriptions will be omitted. In addition, the accompanying drawings are only schematic illustrations of the present disclosure and are not necessarily drawn to scale.

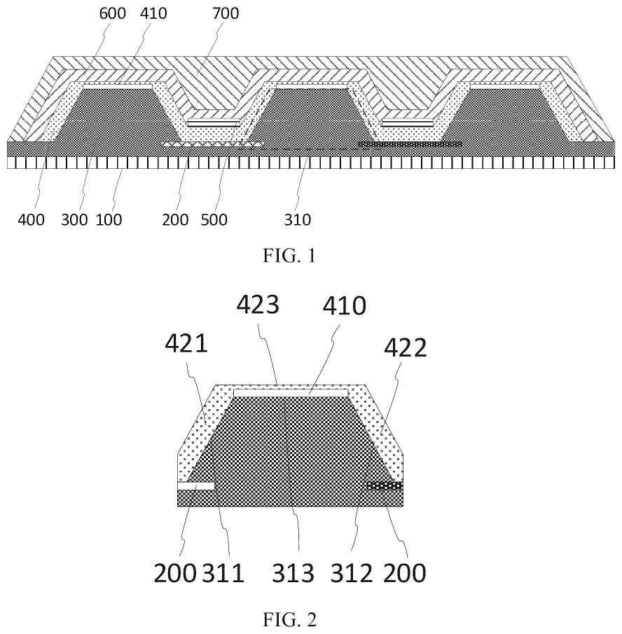

FIG. 1 is a schematic structural diagram of an OLED device according to an implementation of the present disclosure. As shown in FIG. 1, the OLED device may include a substrate 100, an anode layer 200, a pixel-defining layer 300, a first organic layer 400, and a light-emitting layer 500. The anode layer 200 and the pixel-defining layer 300 are provided on a side of the substrate 100, and the pixel-defining layer 300 includes a plurality of pixel-defining structures, adjacent ones of which define a pixel unit pixel units. The first organic layer 400 covers the anode layer 200 and the pixel-defining layer 300, and the light-emitting layer 500 is provided on a side of the first organic layer 400 away from the substrate 100 and is provided within the pixel unit. The first organic layer 400 includes at least one open groove 410.

In the OLED device provided in an embodiment, the open groove 410 is provided in the first organic layer 400, and thus the thickness of the first organic layer 400 at the position of the open groove 410 is reduced to form a high resistance region. This high resistance region can prevent the lateral current from flowing from one pixel unit to another pixel unit, which thus resolve the crosstalk problem due to the lateral leakage.

As shown in FIG. 1, in an embodiment, the first organic layer 400 may include a hole transport layer (HTL) and a hole injection layer (HIL). It is to be understood that the OLED device may also include a second organic layer 600 and a cathode layer 700. The second organic layer 600 may cover the first organic layer 400 and the light-emitting layer 500, and may include an electron transport layer (ETL) and an electron injection layer (EIL). The cathode layer 700 may cover the second organic layer 600. The light-emitting layer 500 is driven to emit light by providing a driving current to the light-emitting layer 500 by applying a voltage between the cathode layer 700 and the anode layer 200. In an embodiment, the material of the anode layer 200 may include a transparent conductive material or a semi-transparent conductive material, such as ITO, Ag, NiO, Al, or graphene, and the material of the cathode layer 700 may include a metal or a combination of metals, for example one of Al, Mg, Ca, Ba, Na, Li, K, and Ag or any combination thereof.

As shown in FIG. 1, in an embodiment, the pixel-defining layer 300 may include a plurality of pixel-defining structures 310. The plurality of pixel-defining structures 310 are spaced apart in an arrangement direction of pixels, and two adjacent pixel-defining structures 310 define one pixel unit. The pixel unit may include an R pixel unit, a G pixel unit, a B pixel unit, and the like. As shown in FIG. 1, the thickness of the pixel-defining layer 300 is greater than the thickness of the anode layer 200. An orthographic projection of the pixel-defining layer 300 on the substrate 100 is at least partially overlapped with an orthographic projection of the anode layer 200 on the substrate 100. In an embodiment, the pixel-defining layer 300 may be made of an organic material such as photoresist. In other embodiments, the pixel-defining layer 300 may also be made of organic material+inorganic material, for example, a complete pixel-defining layer 300 may be obtained by forming a main body structure of the pixel-defining layer using photoresist, and then forming a thin layer on the surface of the main body structure using inorganic material such as SiO₂, SiNₓ.

As shown in FIG. 1, in an embodiment, the thickness of the first organic layer 400 may be reduced by providing the open groove 410 in the first organic layer 400, which equivalently reduce the cross-sectional area of an conductor, so that a high resistance region is formed in this region of the first organic layer 400, which prevents a lateral current from flowing from one pixel unit to another pixel unit, and thus resolves the crosstalk problem due to the lateral leakage. In addition, it should be noted that the current in the pixel unit flows from the anode to the cathode, therefore after the open groove 410 is provided in the first organic layer 400 to block the leakage current, there will be no leakage current flowing through the light-emitting layer 500 of the neighbouring pixel unit, and thus no leakage crosstalk will be caused. Therefore, there is no need to provide an open groove structure in the second organic layer 600 in the present disclosure.

In an embodiment, the pixel-defining structure 310 may have different shapes. FIG. 2 exemplarily shows a schematic structural diagram of a pixel-defining structure in FIG. 1. As shown in FIGS. 1 and 2, the pixel-defining structure 310 may include a first sidewall 311, a second sidewall 312, and a third sidewall 313, and the third sidewall 313 is connected between the first sidewall 311 and the second sidewall 312. Correspondingly, the first organic layer 400 may include a first extending part 421, a second extending part 422, and a third extending part 423, and the third extending part 423 is connected between the first extending part 421 and the second extending part 422. The first extending part 421 corresponds to the first sidewall 311 of the pixel-defining structure 310, the second extending part 422 corresponds to the second sidewall 312 of the pixel-defining structure 310, and the third extending part 423 corresponds to the third sidewall 313 of the pixel-defining structure 310. The first sidewall 311 and the second sidewall 312 may have slope angles, and the third sidewall 313 is parallel to the substrate 100, in other words, the first sidewall 311 and the second sidewall 312 may form sloping surfaces, and the third sidewall 313 forms a horizontal surface connecting the two sloping surfaces. Correspondingly, the first extending part 421 and the second extending part 422 are provided on the sloping surfaces, and the third extending part 423 is provided on the horizontal surface. It should be understood that the horizontal surface described herein means a surface parallel to the substrate 100, which is a relative concept with respect to the sloping surface, and does not refer to a surface which is absolutely horizontal.

In an embodiment, there may be one or more open grooves 410 provided. When there are a plurality of open grooves 410, the plurality of open grooves 410 may be spaced apart in the extension direction of the first organic layer 400. Moreover, when there are a plurality of open grooves 410, the shapes and sizes of the respective open grooves 410 may be the same or different, which is not limited in the present disclosure. In an embodiment, a structure A extending in a B direction means that A may include a major portion and a minor portion connected to the major portion, the major portion is of a line, a line segment or a bar-shaped body, the major portion extends in the B direction, and the length of the major portion extending in the B direction is greater than the length of the minor portion extending in other directions.

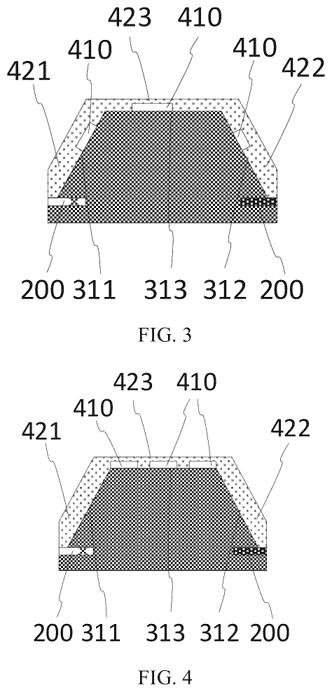

FIG. 3 is a schematic arrangement diagram of open grooves in one pixel-defining structure in FIG. 1, and FIG. 4 is a schematic arrangement diagram of open grooves in another pixel-defining structure in FIG. 1.

In an embodiment, the plurality of open grooves 410 may be arranged in different extending parts of the first organic layer 400, as shown in FIG. 3. For example, the plurality of open grooves 410 may be provided in the first extending part 421 and/or the second extending part 422 and/or the third extending part 423 of the first organic layer 400, in other words, the open grooves 410 may be arranged all on the sloping surface of the pixel-defining structure 310, or arranged partially on the sloping surface of the pixel-defining structure 310 and partially on the horizontal surface of the pixel-defining structure 310. Alternatively, as shown in FIG. 4, the plurality of open grooves 410 may be provided on the same extending part of the first organic layer 400, for example, the first extending part 421 or the second extending part 422 or the third extending part 423, i.e., the plurality of open grooves 410 are all arranged on the sloping surface of the pixel-defining structure 310 or all arranged on the horizontal surface of the pixel-defining structure 310. Alternatively, the first organic layer 400 may include only one open groove 410 as shown in FIG. 2, and the one open groove 410 may be provided on the first extending part 421 or the second extending part 422 or the third extending part 423 of the first organic layer 400, i.e., the one open groove 410 may be provided on the sloping surface of the pixel-defining structure 310 or on the horizontal surface of the pixel-defining structure 310, however the present disclosure is not limited thereto. It is to be understood that when the first organic layer 400 includes only one open groove 410 and the open groove 410 is provided on the horizontal surface of the pixel-defining structure 310, the process difficulty of forming the open groove 410 may be reduced, and a residue may not be easily formed in the pixel opening of the OLED device, and thus the normal emission of the OLED device may not be affected.

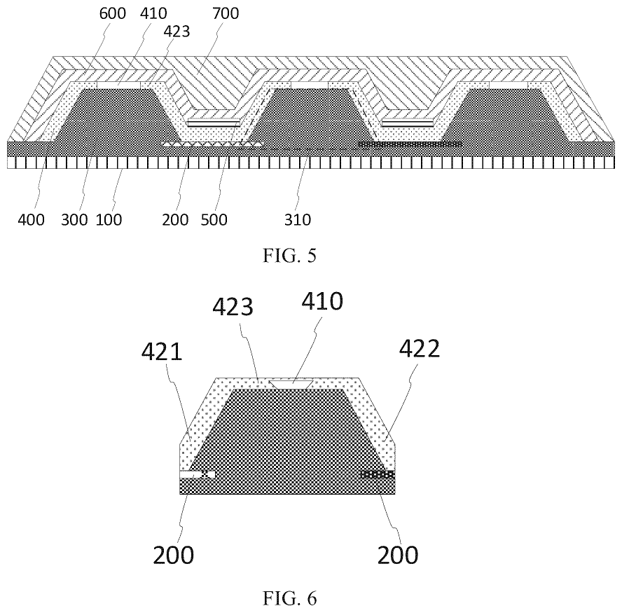

FIG. 5 is a schematic structural diagram of an OLED device according to another embodiment of the present disclosure. As shown in FIG. 5, in some embodiments of the present disclosure, the open groove 410 may penetrate through the first organic layer 400, i.e., may partition the first organic layer 400, which is equivalent to that the first organic layer 400 is partitioned by the plurality of open grooves 410 into a plurality of discrete structures, and two first organic layer structures corresponding to any adjacent pixel units are not connected. It is to be understood that the OLED device shown in FIG. 5 may have all of the features of the OLED device in FIG. 1 except for the depth of the open groove.

In an embodiment, the open groove 410 may have a different shape. For example, as shown in FIG. 1, the open groove 410 may be cuboid, i.e., in a depth direction of the open groove 410, respective cross-sections of the open groove 410 are rectangles with the same area. For example, as shown in FIG. 4, the open groove 410 is provided on the third extending part 423 of the first organic layer 400, and the open groove 410 is cuboid, therefore an orthographic projection of the open groove 410 on the substrate 100 is a rectangle. FIG. 6 is a schematic structural diagram of a portion of an OLED device according to an embodiment of the present disclosure. As shown in FIG. 6, the open groove 410 may have a trapezoidal structure, i.e., in the depth direction of the open groove 410, the respective cross-sections of the open groove 410 are rectangles with areas gradually increased or reduced. For example, the open groove 410 is provided on the third extending part 423 of the first organic layer 400, in this case the orthographic projections of the open groove 410 on the substrate 100 are a plurality of rectangles with the same centers and varying areas. Of course, in other embodiments, the opening groove 410 may have other structures, for example, the opening groove 410 may also have a shape of cylinder, circular truncated cone, cone, and the like. In addition, the sidewall of the opening groove 410 may be curved, for example, the contact surface of the opening groove 410 with the first organic layer 400 may be jagged, which all belong to the protection scope of the present disclosure.

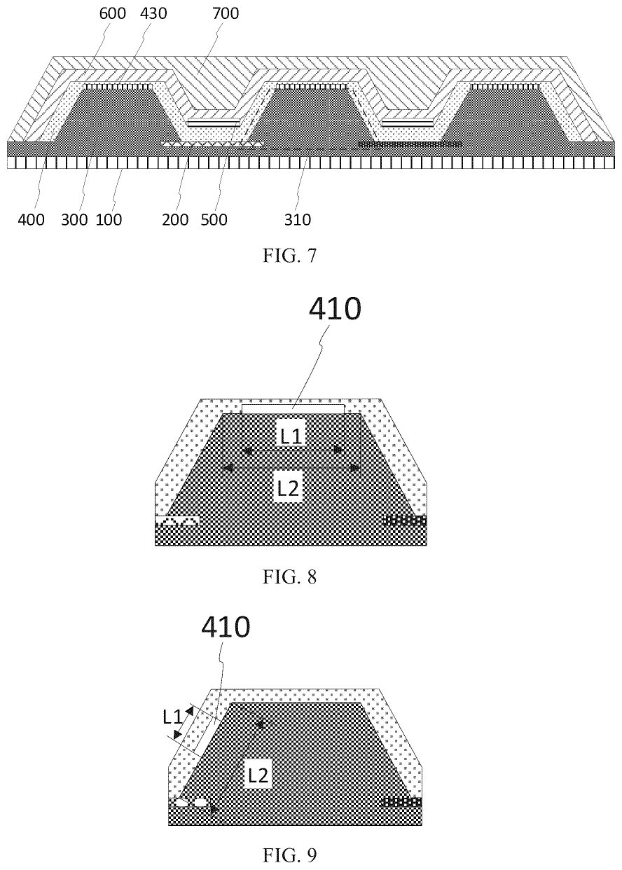

The thickness of the first organic layer 400 is thin, however the process of preparing the open groove 410 on the thin first organic layer 400 is difficult. In order to simplify the process difficulty, in an embodiment, the open groove 410 may include a modification layer 430 therein, which may support the first organic layer 400, preventing the first organic layer 400 and other film layers provided on the first organic layer 400 from falling down and deforming at the open groove 400 and thus affecting the performance of the OLED device. Further, when the open groove 410 incudes the modification layer 430 therein, the process difficulty may be reduced. It is to be understood that the modification layer 430 is provided insulatively, i.e., the lateral current of the first organic layer 400 cannot pass through the modification layer 430. For example, FIG. 7 is a schematic structural diagram of an OLED device according to yet another embodiment of the present disclosure. As shown in FIG. 7, in an embodiment, the modification layer 430 is provided within the open groove 410 and is in contact with the walls of the open groove 410, and the shape of the modification layer 430 matches the shape of the open groove 410. In an embodiment, the surface energy of the modification layer 430 may be set to be less than the surface energy of the pixel-defining layer 300, and then a thin first organic layer 400 may be formed at the location of the modification layer 430 by a deposition process. The formation of the open groove 410 and the modification layer 430 may refer to the subsequent embodiments regarding manufacturing method, which will not be explained herein.

It is to be understood that in other embodiments, the modification layer 430 may also be in partial contact with a wall of the open groove 410, and/or the shapes of the modification layer 430 and the open groove 410 do not match each other, however the present disclosure is not limited thereto.

It is to be understood that in an embodiment, the order in which the open groove 410 and the modification layer 430 are formed may be specifically determined according to the manufacturing process, for example, the modification layer 430 may be formed first, and then the first organic layer 400 may be formed on the modification layer 430, so that the first organic layer 400 has an open groove structure. Of course, in other embodiments, the open groove 410 may be formed in the first organic layer 400 first by other processes, and then the modification layer 430 is formed in the open groove 410, however the present disclosure is not limited thereto.

In an embodiment, the material of the modification layer 430 may be SiO₂. In other embodiments, the modification layer 430 may also be an insulating material doped with negative ions, for example, the modification layer 430 may be obtained by doping the surface of the pixel-defining structure 310 with a negative-ion material. The formation of the modification layer 430 may be referred to the subsequent description in the embodiment regarding the manufacturing method, which will be not be explained here.

As shown in FIG. 7, in an embodiment, the open groove 410 has a recess depth, the thickness of the modification layer 430 may be the same as the recess depth of the open groove 410, and the recess depth of the open groove 410 may be adjusted according to the overall thickness of the first organic layer 400. The recess depth of the open groove 410 may be understood as a depth at which the open groove 410 is recessed in a direction perpendicular to the sidewall of the pixel-defining structure 310. In an embodiment, a ratio of the recess depth of the open groove 410 to the thickness of the first organic layer 400 at the same location as the open groove 410 may be greater than or equal to 1/9 and less than or equal to ⅘, for example, it may be 1/9, 2/9, ⅓, 4/9, 5/9, ⅔, 7/9, ⅘, and the like. Here, the first organic layer 400 at the same location as the open groove 410 may be understood as a portion of the first organic layer 400 that faces the open groove 410 in a direction perpendicular to the sidewall of the pixel-defining structure 310 on which the open groove 410 is located. For example, when the open groove 410 is located on the sloping surface of the pixel-defining structure 310, the first organic layer 400 at the same position as the open groove 410 is a portion of first organic layer 400 that faces the open groove 41 in a direction perpendicular to the sloping surface of the pixel-defining structure 310; or when the open groove 410 is located on the horizontal surface of the pixel-defining structure 310, the first organic layer 400 at the same location as the open groove 410 is a portion of the first organic layer 400 that faces the open groove 410 in a direction perpendicular to the substrate 100. In other words, in an embodiment of the present disclosure, a ratio of the recess depth of the open groove 410 to the total thickness of the first organic layer 400 may be 50% to 90%, for example, 50%, 60%, 70%, 80%, 90%, and the like. The total thickness of the first organic layer 400 described herein is the sum of the recess depth of the open groove 410 and the thickness of the first organic layer 400 at the location corresponding to the open groove 410, or the thickness of the first organic layer 400 at the location where the open groove 410 is not provided. In an embodiment of the present disclosure, the recess depth of the open groove 410 is set based on the above ratio, which can sufficiently reduce the thickness of the first organic layer 400 at a corresponding location by the open groove 410, so that the first organic layer 400 may have a high resistance region, thereby blocking the lateral current in the first organic layer 400. If the recess depth of the open groove 410 is too large, the first organic layer 400 may not be formed at the position of the open groove 410, i.e., the open groove 410 may separate the first organic layer 400; and if the recess depth of the open groove 410 is too small, the thickness of the first organic layer 400 at the position of the open groove 410 is too large to form a high resistance region, thereby reducing the blocking effect on the current. In some embodiments, the recess depth of the open groove 410 is greater than or equal to 1000 Å and less than or equal to 2000 Å, in other words, the thickness of the modification layer 430 may be greater than or equal to 1000 Å and less than or equal to 2000 Å, for example, 1000 Å, 1300 Å, 1500 Å, 1600 Å, 1800 Å, 1900 Å, 2000 Å and the like.

FIG. 8 is a schematic structural diagram of a portion of an OLED device according to another implementation of the present disclosure. As shown in FIG. 8, in an embodiment, a ratio of an opening length of the open groove 410 to a length of the sidewall of the pixel-defining structure 310 corresponding thereto is greater than or equal to 1/10 and less than or equal to 1. In other words, a ratio of an extension length of the modification layer 430 to the length of the sidewall of the pixel-defining structure 310 corresponding thereto may be greater than or equal to 1/10 and less than or equal to 1. It is to be understood that when the size of the open groove 410 is too small, the demand on the process is relatively high. In an embodiment, the open groove 410 is formed according to the above ratio, which may reduce the process difficulty. For example, the opening length of the open groove 410 is L1, the length of the sidewall of the pixel-defining structure 310 in which the open groove 410 is located is L2, and L1/L2 may be 1/10, ⅕, 3/10, ⅖, ½, ⅗, 7/10, ⅘, 9/10, 1, and the like. When the ratio of the opening length of the open groove 410 to the length of the sidewall of the pixel-defining structure 310 is 1, the opening length of the open groove 410 is the same as the length of the sidewall of the pixel-defining structure 310, which may further simplify the process steps and reduce the process difficulty. In an embodiment, the opening length of the open groove 410 refers to the opening length of the open groove 410 in a length direction of the sidewall of the pixel-defining structure 310 in which the open groove 410 is located. For example, as shown in FIG. 8, the open groove 410 is located on the horizontal surface of the pixel-defining structure 310, and the opening length of the open groove 410 is the opening length of the open groove 410 in a direction in which the open groove 410 extends on the horizontal surface. FIG. 9 is a schematic structural diagram of a portion of an OLED device according to yet another implementation of the present disclosure. As shown in FIG. 9, the open groove 410 is located on the sloping surface of the pixel-defining structure 310, and the opening length of the open groove 410 is the opening length of the opening groove 410 in a direction in which the opening groove 410 extends on the sloping surface.

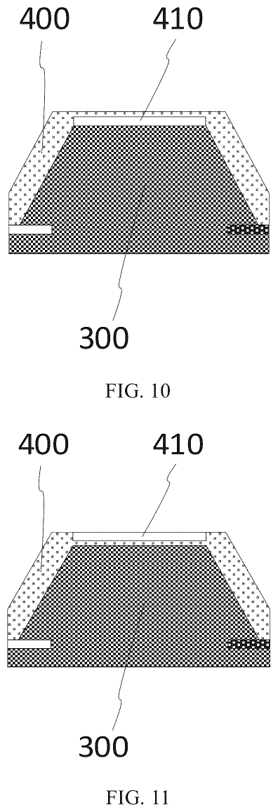

In an embodiment, the open groove 410 may be open toward the pixel-defining structure 310 or away from the pixel-defining structure 310. FIG. 10 is a schematic structural diagram of a portion of an OLED device according to yet another implementation of the present disclosure. As shown in FIG. 10, the open groove 410 is open toward the pixel-defining layer 300, i.e., the opening of the open groove 410 downwardly faces the pixel-defining structure 310. In this structure, when the modification layer 430 is provided in the open groove 410, the modification layer 430 is located on the sidewall of the pixel-defining structure 310 correspondingly, and in such structure, an existing evaporation process may be used to deposit the first organic layer 400 on the modification layer 430, so that the thickness of the first organic layer 400 at the modification layer 430 is thinner than that at the other locations and thus a high resistance region is formed. FIG. 11 is a schematic structural diagram of a portion of an OLED device according to yet another implementation of the present disclosure. As shown in FIG. 11, the open groove 410 may also be open away from the pixel-defining layer 300, i.e., the opening of the open groove 410 upwardly faces away from the pixel-defining structure 310. In this structure, when the modification layer 430 is provided in the open groove 410, the modification layer 430 is in contact with the first organic layer 400 and not in contact with the pixel-defining structure 310, and in such structure, the modification layer 430 may be formed by forming the first organic layer 400, then forming the open groove 410 in the first organic layer 400 by using a patterning process, and filling the open groove 410 with an insulating material. For example, the open groove 410 may be etched by using a half-etching process or an ion-etching process. It is to be understood that regardless of the open groove 410 is open towards or away from the pixel-defining structure 310, the thickness of the first organic layer 400 may be reduced so that the first organic layer 400 has a high resistance region to block the lateral current, thereby preventing the lateral leakage crosstalk.

The present disclosure further provides a method of manufacturing the OLED device according to any embodiment of the present disclosure, and the method includes:
S110, providing a substrate;
S120, forming an anode layer and a pixel-defining layer on the substrate;
S130, forming a buffer layer on the pixel-defining layer;
S140, forming a pixel-defining structure and a buffer structure provided on the pixel-defining structure by patterning the buffer layer and the pixel-defining layer using a patterning process;
S150, forming a first organic layer on the pixel-defining structure and the buffer structure;
S160, etching away the buffer structure using an etching process; and
S170, forming a cathode layer on the first organic layer.

The substrate 100 may be a glass substrate. The material of the anode may include a transparent conductive material or a semi-transparent conductive material, such as ITO, Ag, NiO, Al, or graphene.

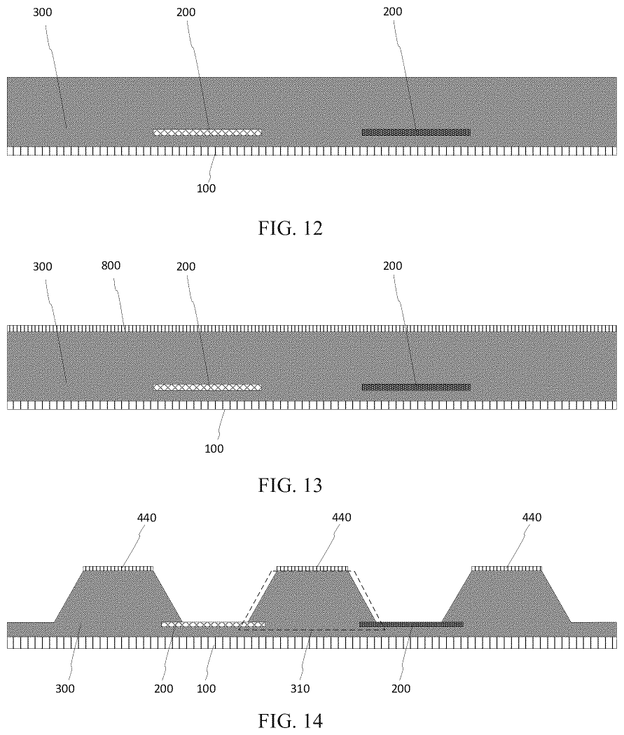

FIG. 12 is a schematic structural diagram in which the anode layer and the pixel-defining layer are formed on the substrate according to an implementation of the present disclosure. As shown in FIG. 12, the pixel-defining layer 300 formed in step S120 may cover the anode layer 200. The pixel-defining layer 300 may be made of an organic material such as photoresist or the like, or may be made of organic material+inorganic material, for example, a complete pixel-defining layer may be obtained by forming a main body structure of the pixel-defining layer by using photoresist, and then forming a thin surface layer on the main body structure by using an inorganic material such as SiO₂, SiNₓ or the like. For example, the organic photoresist material is coated on the substrate 100 on which the anode layer 200 is formed, and the coating method may include slit coating, spin coating or the like. The thickness of the organic photoresist material is higher than the height of the anode layer 200, and the half-etching or ion-etching is performed on the organic photoresist material to remove the organic material layer on the surface of the anode layer 200 so as to form the pixel-defining layer 300.

FIG. 13 is a schematic structural diagram in which the buffer layer is formed according to an implementation of the present disclosure. As shown in FIG. 13, in step S130, the buffer layer 800 may be formed using a photolysis material or a pyrolysis material, and an air hole may be opened at a pre-determined position of the buffer layer 800 so as to etch away the formed buffer structure 440 in step S160.

FIG. 14 is a schematic structural diagram in which the pixel-defining structure and the buffer structure are formed according to an implementation of the present disclosure. As shown in FIG. 14, in step S140, the patterning process may include an exposure developer process. A plurality of pixel-defining structures 310 and the buffer structure 440 provided on the pixel-defining structure 310 may be formed by using the patterning process. The plurality of pixel-defining structures 310 are spaced apart in an extension direction of the pixel-defining layer 300, and two adjacent pixel-defining structures 310 defines one pixel unit. A light-emitting layer 500 may be formed within the pixel unit in a subsequent step. As described in the above-described embodiment, the buffer structure 440 may be provided on the horizontal surface at the top of the pixel-defining structure 310 or on the sloping surface at the side of the pixel-defining structure 310, and the shape of the buffer structure 440 and the extension length thereof may be adapted to the shape of the sidewall of the pixel-defining structure 310 at a corresponding position thereto and the extension length thereof. For example, when the buffer structure 440 is formed at the top of the pixel-defining structure 310, a cuboid-shaped buffer structure 440 may be formed at the top of the pixel-defining structure 310 by the patterning process, and the length of the buffer structure 440 may be the same as the length of the top of the pixel-defining structure 310.

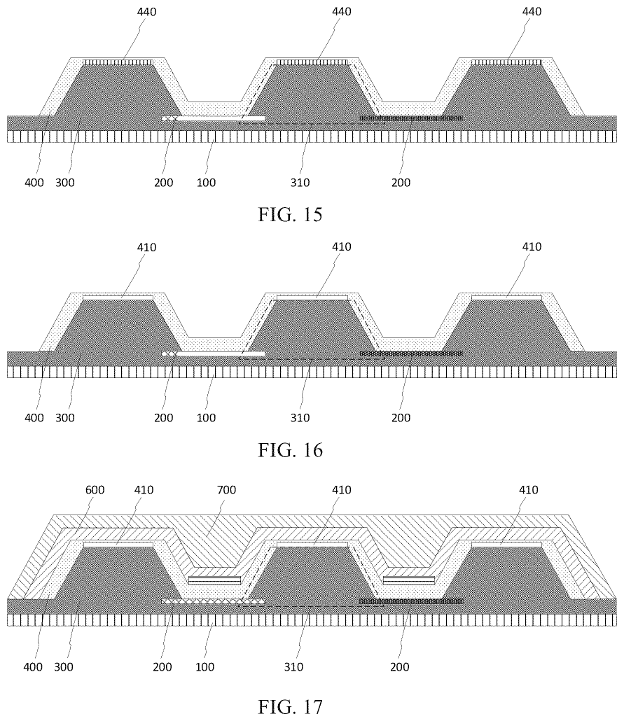

FIG. 15 is a schematic structural diagram in which the first organic layer is formed according to an implementation of the present disclosure. As shown in FIG. 15, the first organic layer 400 may be formed on the pixel-defining structure 310 and the buffer structure 440 using an evaporation process in step S150, including forming a hole-injection layer (HIL) and a hole transport layer (HTL) respectively by the evaporation process.

FIG. 16 is a schematic structural diagram in which the open groove is formed according to an implementation of the present disclosure. As shown in FIG. 16, in step S160, the buffer structure 440 may be etched away using an etching process, thereby forming the open groove at a location of the buffer structure 440. For example, the buffer layer 800 may be made of a photolysis material or a pyrolysis material with air holes at fixed locations of the buffer layer 800. After forming the first organic layer, the buffer structure 440 may be etched away using, for example, a femtosecond laser process, thereby causing the first organic layer to have the open groove without damaging the first organic layer. It is to be understood that in other embodiments, other processes may be used to form the first organic layer with the open groove, and the present disclosure is not limited thereto.

FIG. 17 is a schematic structural diagram in which the OLED device is formed according to an implementation of the present disclosure. As shown in FIG. 17, step S150 is to form the cathode layer. It is to be understood that the OLED device typically further includes a second organic layer 600. The second organic layer 600 may cover the first organic layer 400 and the light-emitting layer 500. The second organic layer 600 may include an electron transport layer (ETL) and an electron injection layer (EIL). On this basis, the cathode layer 700 may be formed on the second organic layer 600. In an embodiment, the material of the cathode layer 700 may include a metal or a combination of metals, such as, for example, one of Al, Mg, Ca, Ba, Na, Li, K, and Ag or any combination thereof.

In the present disclosure, the open groove 410 is provided in the first organic layer, and the open groove 410 may reduce the thickness of the first organic layer, so that the first organic layer has a high resistance region. This high resistance region can block lateral current, and thus resolve the crosstalk problem due to the lateral leakage.

The present disclosure also provides a method of manufacturing another OLED device. The manufacturing method in the present embodiment differs from that in the above embodiments in that in the present embodiment, the buffer layer is to be formed in the open groove, and the material for forming the buffer layer is different from that in the above embodiments, and in the present embodiment, the modification layer is further to be formed. The method of manufacturing the OLED device may include:
S210, providing a substrate;
S220, forming an anode layer and a pixel-defining layer on the substrate;
S230, forming a buffer layer on the pixel-defining layer;
S240, forming a pixel-defining structure and a modification layer located on the pixel-defining structure by patterning the buffer layer and the pixel-defining layer using a patterning process;
S250, forming a first organic layer on the pixel-defining structure and the modification layer; and
S260, forming a cathode layer on the first organic layer.

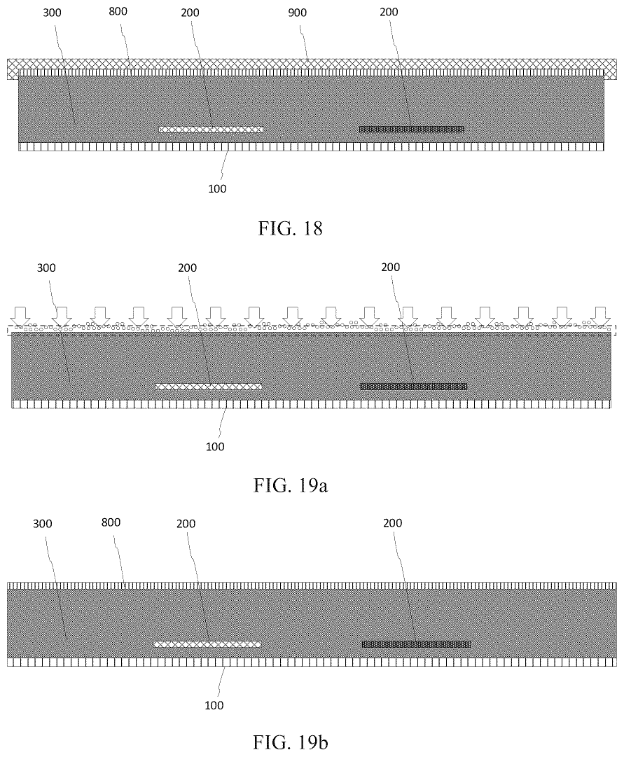

Steps S210 to S230 may refer to the description in the above embodiments, and the structure of the formed buffer layer may refer to FIG. 13. The material for forming the buffer layer in the present embodiment is different from that in the above embodiments. Specifically, in step S230, the buffer layer 800 may be obtained by depositing a first material on the pixel-defining layer 300 using a chemical vapor deposition (CVD) process. The first material may be, for example, SiO_{2,} and a SiO₂ layer may be deposited on the pixel-defining structure 310 using the CVD process to obtain the buffer layer 800, and the buffer layer 800 obtained may have the structure shown in FIG. 13. It is to be noted that after the buffer layer 800 is obtained by depositing the inorganic material using the CVD process, it performs a low surface energy modification on the buffer layer 800 such that the surface energy of the buffer layer 800 is lower than the surface energy of the pixel-defining layer, and in this way, a thin first organic layer may be formed on the modification layer by the deposition process in step S250. For example, FIG. 18 is a schematic diagram of surface energy modification according to an implementation of the present disclosure. As shown in FIG. 18, the buffer layer 800 may be immersed into a 1H,1H,2H,2H-perfluoroalkyltriethoxysilane solution 900 for a predetermined time, and then is dried. For example, the 1H, 1H,2H,2H-perfluoroalkyltriethoxysilane solution 900 may be obtained by incorporating 1H, 1H,2H,2H-perfluoroalkyltriethoxysilane into water or ethyl alcohol so that a mass fraction ratio of 1H, 1H,2H,2H-perfluoroalkyltriethoxysilane with respect to water or ethyl alcohol is 0.5% to 1.5% (e.g., 0.5%, 0.8%, 1.0%, 1.2%, 1.5% and the like). The buffer layer 800 is immersed into the solution for 120 s, and then dried at 120° C., so the low surface energy modification of the buffer layer 800 is completed. Therefore, the surface energy of the modification layer 430 formed on the basis of the buffer layer 800 is lower than that of the pixel-defining layer 300.

Alternatively, the buffer layer 800 may be formed by doping a surface of the pixel-defining layer 300 with a second material using an ion implantation process. The formed buffer layer 800 also has a surface energy lower than the surface energy of the pixel-defining layer 300. For example, FIG. 19a is a schematic diagram of a process for forming a buffer layer according to an implementation of the present disclosure, and FIG. 19b is a schematic structural diagram of a buffer layer formed according to the process shown in FIG. 19a. As shown in FIGS. 19a and 19b, the buffer layer 800 may be formed by doping a surface of the pixel-defining layer with a second material, and the second material may be an electronegative particle material, e.g., an F-fluoride ion. It may perform an F-fluoride ion doping process on the pixel-defining layer 300 by using an ion implantation method to form the buffer layer 800. As the fluoride ions have a large electronegativity, they are more likely to bind the electrons on the surface of a material, making it more difficult for the electrons on the surface of the material to combine with foreign reactive groups, thereby allowing for the evaporation of a thinner first organic layer at that location. It is to be understood that the second material may also be other electronegative ion materials.

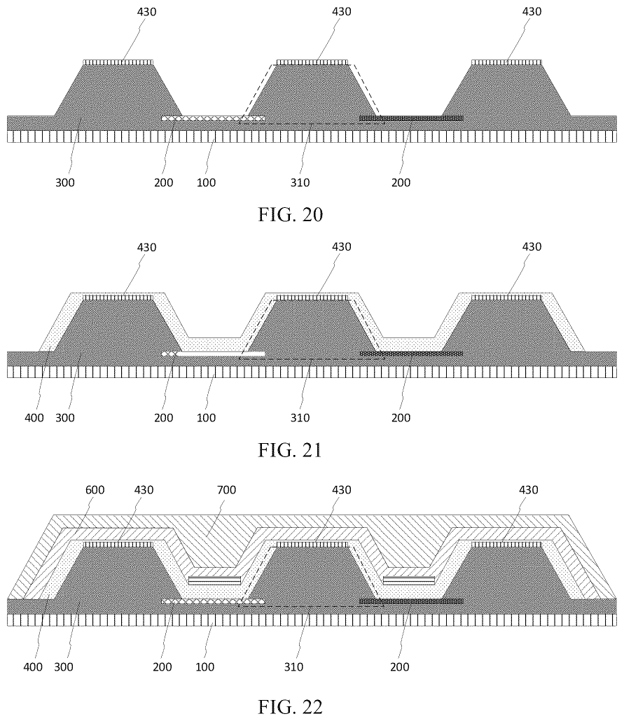

FIG. 20 is a schematic structural diagram in which the pixel-defining structure and the modification layer are formed according to an implementation of the present disclosure. As shown in FIG. 20, in step S240, the pixel-defining structure 310 and modification layer 430 are formed by a patterning process. The modification layer 430 is a structure formed after etching the buffer layer 800. It is to be understood that the formed pixel-defining structure 310 and modification layer 430 may have a similar structure to the pixel-defining structure 310 and the buffer structure 440 in FIG. 14, which will not be repeated herein.

FIG. 21 is a schematic structural diagram in which the first organic layer is formed according to an implementation of the present disclosure. As shown in FIG. 21, the first organic layer 400 may be formed by an evaporation process in step S250. For example, a hole injection layer (HIL), and a hole transport layer (HTL) are evaporated, respectively. Obviously, when the modification layer 430 is provided, in the process of forming the first organic layer 400, since the surface energy of the modification layer 430 is lower than the surface energy of the pixel-defining structure 310, the adhesive force of the evaporation particles of the first organic layer 400 on the modification layer 430 is weakened, and the thickness of the deposited thickness thereof is reduced, resulting in the formation of a high resistance region, i.e., the thickness of the first organic layer 400 at the location corresponding to the modification layer 430 is smaller than the thickness of the first organic layer 400 at the location without the modification layer 430. Similarly, when the buffer layer 800 is formed by doping the surface of the pixel-defining layer 300 using the ion implantation process in step S230, since the surface energy of the buffer layer 800 formed by the doped fluorine ions is lower than the surface energy of the pixel-defining structure 310, therefore when the first organic layer 400 is evaporated, differential deposition of the first organic layer 400 may be achieved, i.e., a thin first organic layer 400a is formed on the modification layer 430 with a low surface energy to form a high resistance region.

In an embodiment, the modification layer 430 is formed on the pixel-defining structure 310, and the surface energy of the modification layer 430 is lower than that of the pixel-defining structure 310, therefore differential deposition of the material of the first organic layer 400 is achieved during the evaporation process, and the thickness of first organic layer 400 at the location corresponding to the low surface energy is small, i.e., a thin first organic layer 400 is formed on the modification layer 430, and the thin first organic layer 400 forms a high resistance region which can block the current, so that the lateral current is difficult to pass through the high resistance region during the operation of the OLED device, and the undesirable crosstalk phenomenon due to the lateral leakage can be effectively eliminated.

It is to be understood that after forming the first organic layer 400, the light-emitting layer 500 may be formed within the pixel unit by an evaporation process, and the cathode layer 700 may be formed. The cathode layer 700 covers the anode layer 200 and the first organic layer 400 to form a complete OLED device.

FIG. 22 is a schematic structural diagram of an OLED device formed according to an implementation of the present disclosure. As shown in FIG. 22, in step S260, the cathode layer is formed, and as described in the above embodiment, the OLED device typically also includes a second organic layer 600, the second organic layer 600 may cover the first organic layer 400 and the light-emitting layer 500, and the second organic layer 600 may include an electron transport layer (ETL)) and an electron injection layer (EIL). On this basis, the cathode layer 700 may be formed on the second organic layer 600.

It is to be understood that in an embodiment, the material of the anode layer, the material of the pixel-defining layer, and the material of the cathode layer may all be the same as that in the above-described embodiments, which will not be repeated herein.

Those skilled in the art may easily conceive of other embodiments of the present disclosure upon consideration of the specification and practice of the invention disclosed herein. The present disclosure is intended to cover any variations, uses, or adaptations of the present disclosure that follow the general principles of the present disclosure and include the common general knowledge or conventional technical means in the technical field not disclosed by the present disclosure. The specification and embodiments are to be regarded as exemplary only, with the true scope and spirit of the present disclosure being indicated by the following claims.

1. An OLED device, comprising:
a substrate;
an anode layer and a pixel-defining layer, provided on a side of the substrate, the pixel-defining layer comprising a plurality of pixel-defining structures, and adjacent pixel-defining structures defining a pixel unit;
a first organic layer, covering the anode layer and the pixel-defining layer;
a light-emitting layer, provided on a side of the first organic layer away from the substrate and within the pixel unit; and
a cathode layer, covering the light-emitting layer and the first organic layer,
wherein the first organic layer comprises at least one open groove.

2. The OLED device according to claim 1, wherein the pixel-defining structure comprises a first sidewall, a second sidewall and a third sidewall, and the third sidewall is connected between the first sidewall and the second sidewall; and
the first organic layer comprises a first extending part, a second extending part, and a third extending part, and the first extending part, the second extending part and the third extending part are provided to respectively correspond to the first sidewall, the second sidewall and the third sidewall; and
the open groove is provided in at least one of the first extending part, the second extending part and the third extending part.

3. The OLED device according to claim 2, wherein the open groove is provided with a modification layer therein for insulation.

4. The OLED device according to claim 3, wherein a ratio of a thickness of the modification layer to a thickness of the first organic layer at a same location as the modification is greater than or equal to 1/9 and less than or equal to ⅘.

5. The OLED device according to claim 4, wherein the thickness of the modification layer is greater than or equal to 1000 Å and less than or equal to 2000 Å.

6. The OLED device according to claim 3, wherein a ratio of an extension length of the modification layer to a length of a sidewall, corresponding to the modification layer, of the pixel-defining structure is greater than or equal to 1/10 and less than or equal to 1.

7. The OLED device according to claim 3, wherein a material of the modification layer is SiO₂ or an insulating material doped with negative ions.

8. The OLED device according to claim 3, wherein a surface energy of the modification layer is less than a surface energy of the pixel-defining layer.

9. The OLED device according to claim 1, wherein an orthographic projection, on the substrate, of the anode layer is partially overlapped with an orthographic projection, on the substrate, of the pixel-defining structure adjacent to the anode layer, and an orthographic projection, on the substrate, of the light-emitting layer is within the orthographic projection, on the substrate, of the anode layer; and
wherein an orthographic projection, on the substrate, of the open groove is not overlapped with the orthographic projection, on the substrate, of the light-emitting layer.

10. The OLED device according to claim 1, wherein
the open groove is open towards the pixel-defining structure or away from the pixel-defining structure.

11. The OLED device according to claim 2, wherein one open groove is provided, the one open groove is provided in the first extending part of the first organic layer, the open groove is provided with a modification layer therein for insulation, and
an orthographic projection, on the substrate, of the third sidewall of the pixel-defining structure is within an orthographic projection, on the substrate, of the modification layer.

12. A method of manufacturing the OLED device according to claim 1, comprising:
providing a substrate;
forming an anode layer and a pixel-defining layer on the substrate;
forming a buffer layer on the pixel-defining layer;
forming a pixel-defining structure and a buffer structure provided on the pixel-defining structure by patterning the buffer layer and the pixel-defining layer using a patterning process;
forming a first organic layer on the pixel-defining structure and the buffer structure;
forming an open groove by etching away the buffer structure using an etching process; and
forming a cathode layer on the first organic layer.

13. A method of preparing the OLED device according to claim 3, comprising:
providing a substrate;
forming an anode layer and a pixel-defining layer on the substrate;
forming a buffer layer on the pixel-defining layer;
forming a pixel-defining structure and a modification layer by patterning the buffer layer and the pixel-defining layer using a patterning process;
forming a first organic layer on the pixel-defining structure and the modification layer; and
forming a cathode layer on the first organic layer.

14. The method according to claim 13, wherein forming the buffer layer on the pixel-defining layer comprises:
forming the buffer layer by depositing a first material on the pixel-defining layer using a chemical vapor deposition process.

15. The method according to claim 14, wherein the method further comprises, after forming the buffer layer:
modifying the buffer layer using a low surface energy modification process such that the surface energy of the buffer layer is lower than the surface energy of the pixel-defining layer.

16. The method according to claim 15, wherein modifying the buffer layer using the low surface energy modification process comprises:
immersing the buffer layer into a predetermined solution for a predetermined time; and
drying the buffer layer at a predetermined temperature.

17. The method according to claim 16, wherein a material of the buffer layer is SiO₂, and immersing the buffer layer into the predetermined solution for the predetermined time comprises:
immersing the buffer layer of SiO₂ into a 1H,1H,2H,2H-perfluoroalkyltriethoxysilane solution for 120 s, wherein the 1H,1H,2H,2H-perfluoroalkyltriethoxysilane solution contains 1H,1H,2H,2H-perfluoroalkyltriethoxysilane with a mass fraction of 0.5% to 1.5% with respect to a solvent, and the solvent is water or ethyl alcohol,
drying the buffer layer at the predetermined temperature comprises:
drying the buffer layer of SiO₂ at 120° C.

18. The method according to claim 13, wherein forming the buffer layer on the pixel-defining layer comprises:
forming the buffer layer by doping a surface of the pixel-defining layer with negative ions using an ion implantation process.

19. A display panel comprising the OLED device according to claim 1.
